(19) United States
(12) Patent Application Publication
(10) Pub. No.: US 2022/0253579 A1
(43) Pub. Date: Aug. 11, 2022

(54) Hardware and Software Product Development Using Supervised Learning

(71) Applicant: LynxAI Corp., San Jose, CA (US)

(72) Inventors: Bindiganavale S. Nataraj, Cupertino, CA (US); Dipak Shah, San Jose, CA (US)

(21) Appl. No.: 17/509,352

(22) Filed: Oct. 25, 2021

Related U.S. Application Data
(60) Provisional application No. 63/256,421, filed on Oct. 15, 2021.
(60) Provisional application No. 63/148,430, filed on Feb. 11, 2021.

(51) Int. Cl. G06F 30/27

(52) U.S. Cl. CPC G06F 30/27

(57) ABSTRACT

A method of electronic hardware development includes training a machine-learning model to replicate behavior of a hardware system under development, using output of a first model of the hardware system. The machine-learning model is distinct from the first model. The method also includes providing first test data as inputs to the machine-learning model, receiving results for the first test data from the machine-learning model, and analyzing the results for the first test data to identify any errors.

### RELATED APPLICATIONS

This application claims priority to U.S. Provisional Patent Applications No. 63/148,430, filed on Feb. 11, 2021, and No. 63/256,421, filed on Oct. 15, 2021, which are incorporated by reference in their entirety.

### TECHNICAL FIELD

This disclosure relates to the development of electronic hardware, and more specifically to creating a machine-learning model of the hardware and using the machine-learning model to develop the hardware.

### BACKGROUND

FIG. 1 shows a development system 100 for developing an electronic hardware system (e.g., a computer hardware system). The electronic hardware system is referred to herein as a hardware system for simplicity. During development of the hardware system, different models of the hardware system are created. These models replicate the desired behavior of the hardware system to varying degrees, with varying levels of abstraction. Examples of these models include a behavioral hardware model 104 (also referred to as a behavioral model), a field-programmable-gate-array (FPGA) prototype 106 (i.e., a model instantiated in an FPGA), and a hardware-emulator prototype 108 (i.e., a model instantiated in a hardware emulator). The hardware emulator may be a multi-core processor (e.g., multi-core central-processing unit (CPU)) system.

Software (e.g., one or more applications) for use with the hardware system is developed in a software/API ecosystem 102. (API stands for application programming interface.) The software may be tested against a model (e.g., the behavioral model 104, FPGA prototype 106, or hardware emulator 108) by providing instructions and corresponding data to the model through an API and receiving results from the model through the API. Once development of the hardware system is complete and the hardware system has been fabricated, system-level testing 110 of the software may be performed on a device under test (DUT). The device under test is an instance of the hardware system.

Discrepancies between the software and any of the models can cause significant delays to the hardware-development process. For example, errors resulting from miscommunication (e.g., inaccuracies or a lack of clarity in a document specifying the architecture of the hardware system) can cause the software to be incompatible with the hardware. Resolving such discrepancies causes lengthy, unproductive delays.

### SUMMARY

According, there is a need for systems and methods for cross-platform validation during hardware development.

In some embodiments, a method of hardware development includes training a machine-learning model to replicate behavior of a hardware system under development, using output of a first model of the hardware system. The machine-learning model is distinct from the first model. The method also includes providing first test data as inputs to the machine-learning model, receiving results for the first test data from the machine-learning model, and analyzing the results for the first test data to identify any errors.

In some embodiments, a computer system includes one or more processors and memory storing one or more programs for execution by the one or more processors. The one or more programs include instructions for performing the above method. In some embodiments, a non-transitory computer-readable storage medium stores one or more programs configured for execution by a computer system. The one or more programs include instructions for performing the above method.

### BRIEF DESCRIPTION OF THE DRAWINGS

For a better understanding of the various described implementations, reference should be made to the Detailed Description below, in conjunction with the following drawings.

FIG. 1 shows a development system for developing a hardware system.

FIG. 2 shows a development system for developing a hardware system in accordance with some embodiments.

FIG. 3 shows an alternative development system for developing a hardware system in accordance with some embodiments.

FIG. 4 shows a system used by a hardware developer to develop a model of the hardware system and to train a smart model, in accordance with some embodiments.

FIG. 5 is a flowchart showing a method of training a smart model in accordance with some embodiments.

FIG. 6 shows an example of test data that may be provided as inputs to a smart model, in accordance with some embodiments.

FIG. 7 shows a development system for developing a hardware system in accordance with some embodiments.

FIG. 8 is a flowchart illustrating a hardware-development method in accordance with some embodiments.

FIG. 9 is a block diagram of a computer system used for hardware development, in accordance with some embodiments.

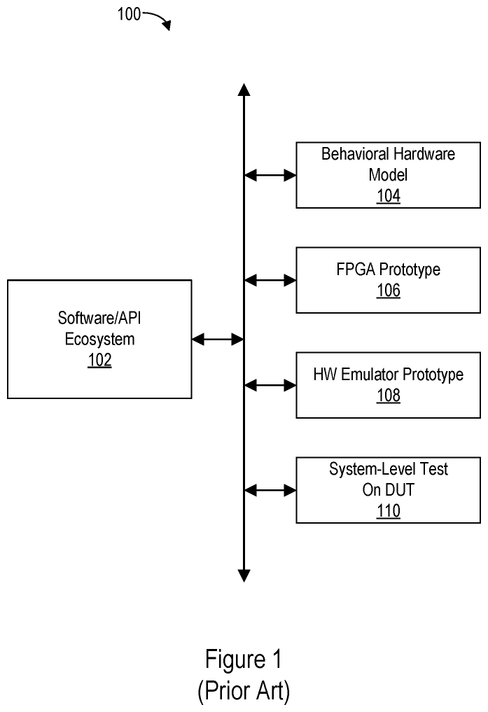

Like reference numerals refer to corresponding parts throughout the drawings and specification.

### DETAILED DESCRIPTION

Reference will now be made in detail to various embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

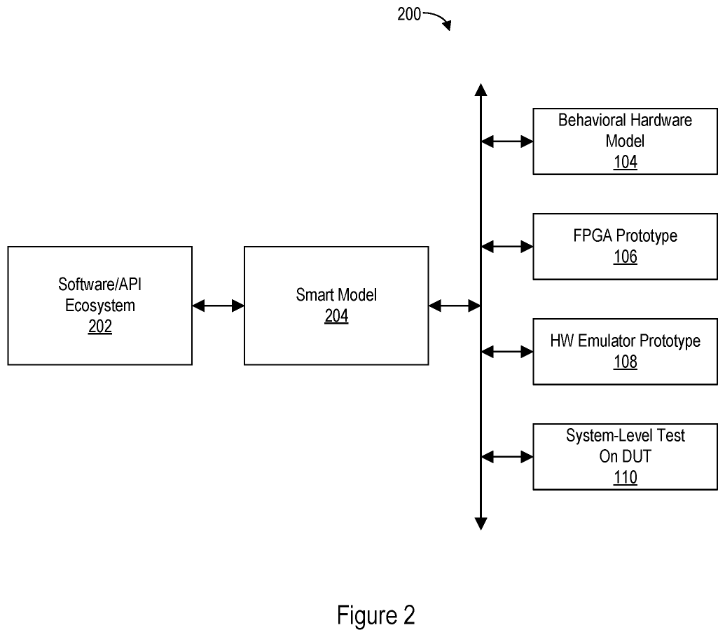

FIG. 2 shows a development system 200 for developing a hardware system in accordance with some embodiments. In some embodiments, the hardware system to be developed using the development system 200 is a system on a semiconductor chip (i.e., a system on a chip (SoC)) or on multiple interconnected semiconductor chips. For example, the hardware system may be an application-specific integrated circuit (ASIC). In another example, the hardware system may be a multi-chip module with a plurality of semiconductor dice in a single semiconductor package (e.g., with the plurality of semiconductor dice stacked in the package). The plurality of semiconductor dice in the package may be referred to as chiplets. In yet another example, the hardware system may be a plurality of semiconductor chips mounted and interconnected on a circuit board or on multiple interconnected circuited boards.

In the development system 200, a machine-learning model 204, referred to as a smart model 204, is disposed between a software/API ecosystem 202 and various models, including the behavioral model 104, FPGA prototype 106 (or a prototype instantiated in another type of programmable logic), and hardware-emulator prototype 108. Each model replicates behavior of the hardware system by modeling all or a portion of the hardware system. Different models may have different degrees of abstraction and different levels of accuracy. In some embodiments, the behavioral model 104 may be created early in the development process while the architecture of the hardware system is being defined. The behavioral model 104 may be a skeleton model that has a high degree of abstraction. For example, the behavioral model 104 may not be cycle accurate. The FPGA prototype 106 may be more accurate than the behavioral model 104. For example, the FPGA prototype 106 may be verified at the input/output (i.e., serializer/deserializer (serdes)) level and may be cycle-accurate. The hardware-emulator prototype 108 may be more accurate than the behavioral model 104 and/or the FPGA prototype 106 but may still have some degree of abstraction compared to the actual hardware system.

In some embodiments, the smart model 204 includes a neural network (e.g., a convolutional neural network (CNN)). The smart model 204 may be trained through supervised learning using output from a particular model, and may subsequently be re-trained through supervised learning using output from an updated version of the particular model and/or using output from a different model. For example, the smart model 204 is initially trained using output from the behavioral model 104, through supervised learning. The output from the behavioral model 104 is provided as input to the smart model 204 during the supervised learning. If changes are later made to the behavioral model 104 to update the behavioral model 104, the smart model is re-trained using output from the updated behavioral model 104, through supervised learning. Later in the hardware-development process, the FPGA prototype 106 may become available, and the smart model 204 is re-trained using output from the FPGA prototype 106, through supervised learning. The output from the FPGA prototype 106 is provided as input to the smart model 204 during the supervised learning. Still later in the hardware-development process, the hardware-emulator prototype 108 may become available, and the smart model 204 is re-trained using output from the hardware-emulator prototype 108, through supervised learning. The output from the hardware-emulator prototype 108 is provided as input to the smart model 204 during the supervised learning.

At any time once the smart model 204 has been initially trained or re-trained, the smart model 204 may be used to test software. The software is developed in a software/API ecosystem 202. The software provides test data to the smart model 204 through an API in the software/API ecosystem 202 and receives results for the test data from the smart model 204 through the API. The test data may include instructions and corresponding data (i.e., data to be processed in accordance with the instructions). In some embodiments, the test data are synthetic data (e.g., as generated through simulation). The results are analyzed to identify errors. The errors may be due to errors in the software, errors in the smart model 204 due to imperfect training, and/or errors in the model used to train the smart model 204 (e.g., errors in the behavioral model 104, FPGA prototype 106, or hardware-emulator prototype 108). Identifying the errors may include identifying out-of-scope conditions in the results and/or out-of-sequence results.

In some embodiments, after the smart model 204 has been trained or re-trained but before it has been used to test software, the smart model 204 is converted to (e.g., published as) run-time executable code. This run-time executable code is used to test the software. Alternatively, the smart model 204 is used to test the software in the same format in which it was trained.

Once the hardware system has been completed and fabricated, the smart model 204 may be re-trained through system-level test 110 of a DUT (i.e., of an instance of the hardware system). Output of the DUT obtained through the system-level test 110 is provided as input to the smart model 204 to re-train the smart model 204 using supervised learning. The software developed in the software/API ecosystem 202 then may be tested against the re-trained smart model 204 (e.g., with the re-trained smart model 204 having been converted to run-time executable code). Errors in the results of this testing may be due to errors in the software, errors in the smart model 204 due to imperfect training, and/or errors in the DUT (e.g., bugs in the hardware system).

The smart model 204 thus may be repeatedly (e.g., continuously) improved through re-training at different stages of hardware development. At each stage of hardware development, the smart model 204 may serve as a golden model for the next stage. The smart model 204 allows validation to be performed across multiple platforms, with the platforms including the software and the models. The smart model 204, once trained or re-trained, replaces the behavioral model 104, FPGA prototype 106, hardware-emulator prototype 108, and system-level testing 110 for software testing.

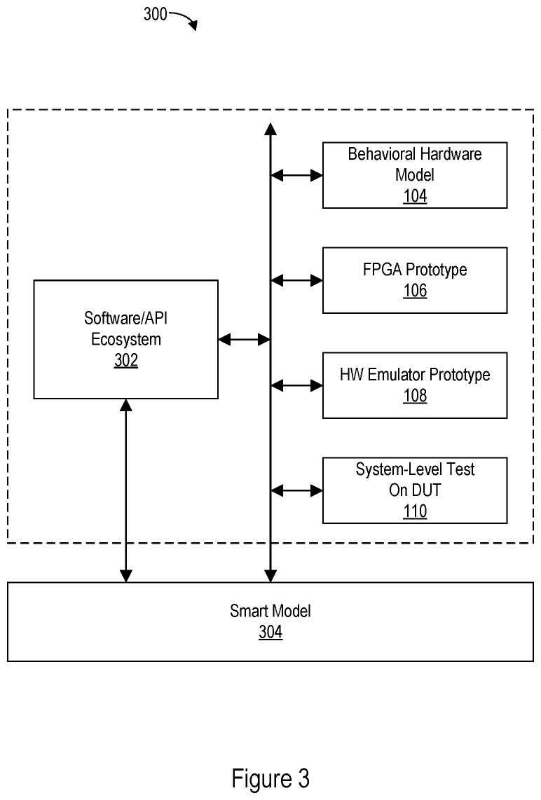

FIG. 3 shows an alternative development system 300 for developing a hardware system in accordance with some embodiments. In the development system 300, software developed in a software/API ecosystem 302 may be tested using a smart model 304, which is a machine-learning model (e.g., including a neural network, such as a CNN). The smart model 304 is trained in the same manner as the smart model 204 (FIG. 2). The software may send test data to the smart model 304 (e.g., as converted to run-time executable code) through an API (e.g., a first API) in the software/API ecosystem 302 and receive results for the test data from the smart model 304 through the API. In some embodiments, the test data are synthetic data (e.g., as generated through simulation). The software also may be tested using the behavioral model 104, FPGA prototype 106, hardware-emulator prototype 108, and/or system-level testing 110. The software may send test data to the behavioral model 104, FPGA prototype 106, hardware-emulator prototype 108, and/or system-level testing 110 through an API (e.g., a second API distinct from the first API) in the software/API ecosystem 302 and receive results from the behavioral model 104, FPGA prototype 106, hardware-emulator prototype 108, and/or system-level testing 110 through the API. The results are analyzed to detect errors (e.g., as in the development system 200, FIG. 2).

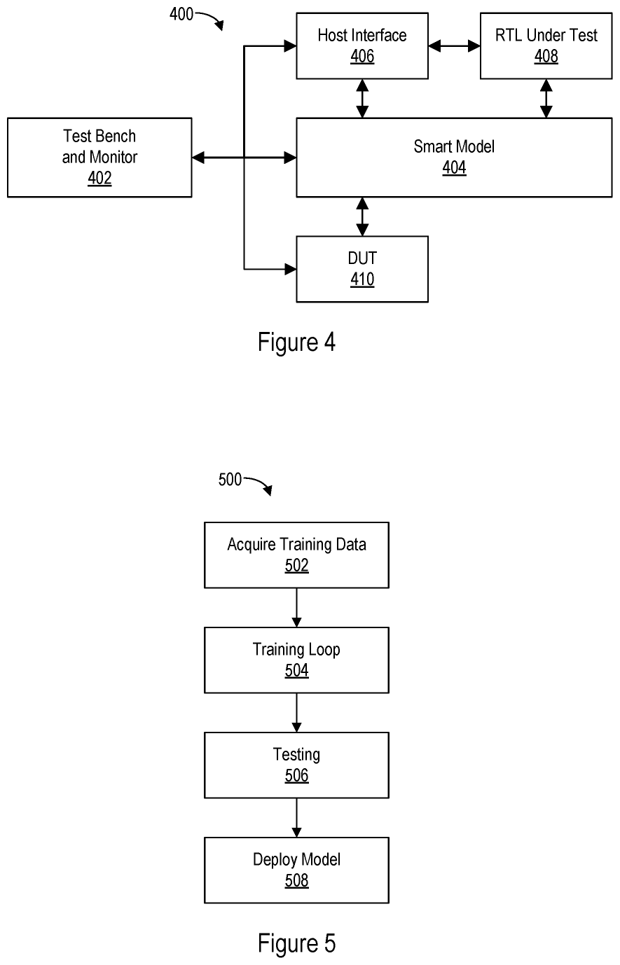

FIG. 4 shows a system 400 used by a hardware developer to develop a model of the hardware system (e.g., the behavioral model 104, FPGA prototype 106, or hardware-emulator prototype 108) and to train a smart model 404, in accordance with some embodiments. The smart model 404 may be an example of the smart model 204 (FIG. 2) or 304 (FIG. 3). The hardware developer uses a test bench and monitor 402, which is communicatively coupled to both a host interface 406 and the smart model 404. In some embodiments, the model (e.g., the behavioral model 104, FPGA prototype 106, or hardware-emulator prototype 108) includes or is based on register-transfer-language (RTL) code 408, which may be stored on a host system. The test bench and monitor 402 may access the RTL code 408 through the host interface 406 and may be used to test the RTL code 408 through the host interface 406. The host interface 406 and/or RTL code 408 may communicate with the smart model 404 to train the smart model 404. For example, output from execution of the RTL code 408, along with input to the RTL code 408, is provided as input to the smart model 404 during supervised learning. Once trained, the smart model 404 may replace the host interface 406 and RTL code 408.

Alternatively, or in addition, the test bench and monitor 402 is communicatively coupled to a DUT 410 (i.e., an instance of the hardware system under test). The test bench and monitor 402 may access the DUT 410 to test the DUT 410. The DUT 410 may communicate with the smart model 404 to train the smart model 404. For example, input to and output from the DUT 410 are provided as input to the smart model 404 during supervised learning.

FIG. 5 is a flowchart showing a method 500 of training a smart model (e.g., smart model 204, FIG. 2; 304, FIG. 3; and/or 404, FIG. 4) in accordance with some embodiments. In the method 500, training data is acquired (502) from a model of a hardware system (e.g., the behavioral model 104, FPGA prototype 106, or hardware-emulator prototype 108, FIGS. 2 and/or 3) or from system-level test 110 (FIGS. 2 and/or 3) of an instance of the hardware system (i.e., of a DUT). The training data includes output from the model or from the system-level test 110. The training data is provided to the smart model (e.g., in batches) during a training loop 504, in accordance with supervised learning. The trained smart model may not replicate the behavior of the model of the hardware system perfectly, but instead will have an associated training loss. The training loss quantifies a difference between the output of the smart model and the expected output. The training loss is determined as part of training the smart model.

Once the training loop 504 is complete, testing (506) is performed to verify that the smart model has been properly trained. The smart model is then deployed (508). Deploying the smart model may include making the smart model available through an API to software in a software/API ecosystem (e.g., software/API ecosystem 202, FIG. 2, or 302, FIG. 3) for testing of the software. Deploying the smart model may include converting the smart model to (e.g., publishing the smart model as) run-time executable code (e.g., which may be available through the API). The method 500 may be performed repeatedly during the hardware-development process in response to updates to models and/or development of new models.

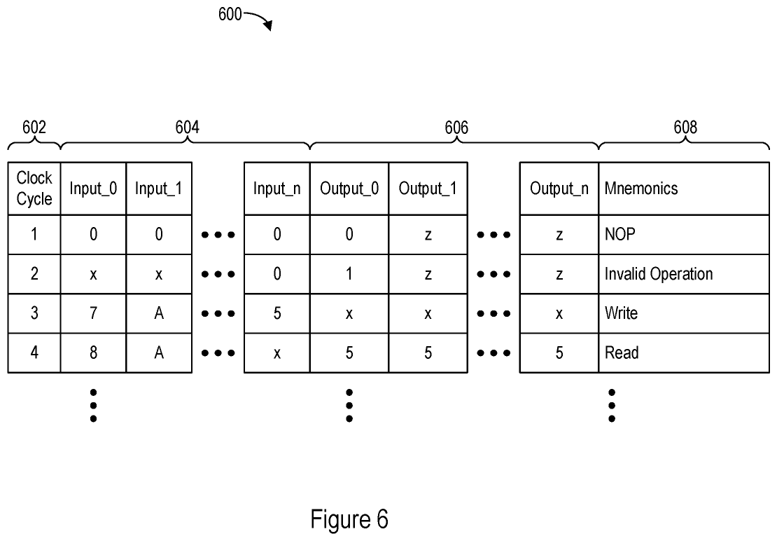

FIG. 6 shows an example of test data 600 that may be provided as inputs to a smart model (e.g., smart model 204, FIG. 2; 304, FIG. 3; and/or 404, FIG. 4), in accordance with some embodiments. The test data 600 may be provided to the smart model when training the smart model and/or when using the smart model to test software in a software/API ecosystem (e.g., software/API ecosystem 202, FIG. 2 or 302, FIG. 3). The test data 600 is divided into clock cycles 602, with each clock cycle corresponding to a respective clock cycle in the hardware system. The clock cycles 602 thus serve as a reference time base. The test data 600 for a particular clock cycle 602 (e.g., for each clock cycle 602) includes input data 604, output data (i.e., expected outputs) 606, and mnemonics 608. The mnemonics 608 specify operations to be performed using corresponding input data 604 (e.g., for the same clock cycle 602). Fields in the input data 604 and output data 606 may specify particular values or specify that respective values are unknown (as specified by “x” in FIG. 6). Unknown values may occur, for example, during hardware-system initialization. Fields in the output data 606 may also specify that an output is expected to be tri-stated (as specified by “z” in FIG. 6) during particular clock cycles 602.

When training the smart model, the test data 600 may be divided into batches and provided to the smart model in those batches. Each batch includes a series of successive clock cycles (i.e., includes the test data for the series of successive clock cycles). In some embodiments, successive batches partially overlap. This overlap in a particular batch allows the smart model to remember previous cycles from the previous batch, thereby providing lookback to previous conditions. This lookback increases the accuracy of the smart model.

In some embodiments, the batches have a number (or respective numbers) of clock cycles equal to a multiple of the latency of the hardware system. This arrangement ensures that outputs data 606 associated with respective input data 604 and mnemonics 608 is found in the same batch as the respective input data 604 and mnemonics 608.

Training loss may be determined and provided on a batch-by-batch basis. An unexpected increase in training loss (e.g., an increase that satisfies a threshold) may indicate a problem with the training process.

The mnemonics 608 and alpha-numeric characters (e.g., “x” and “z”) in the input data 604 and output data 606 are converted to numerical representations that the smart model can process. These numerical representations are referred to as embeddings.

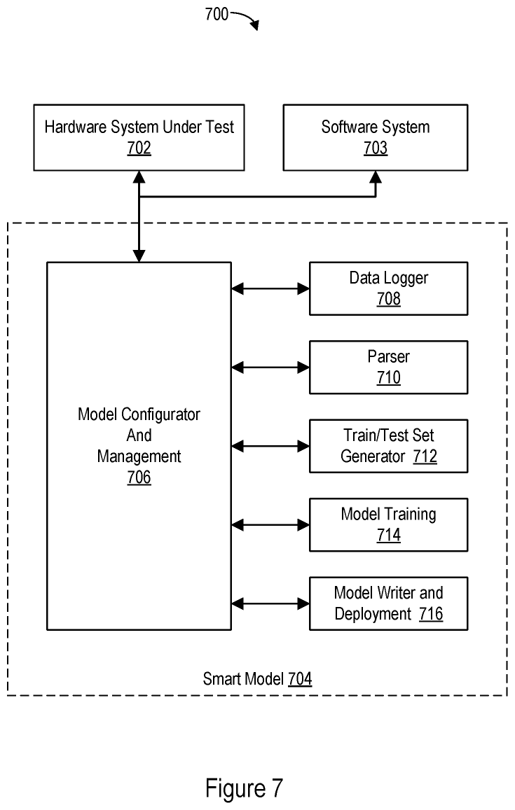

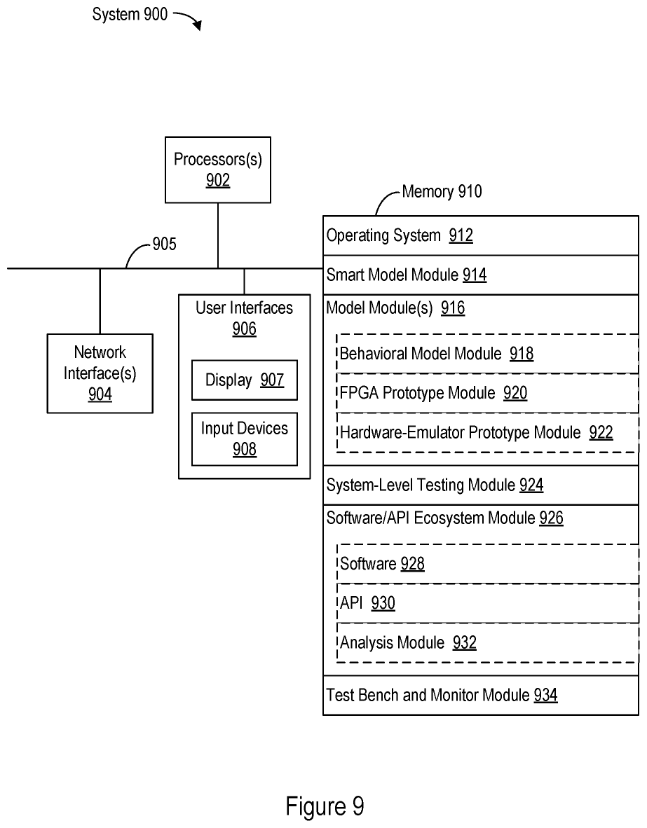

FIG. 7 shows a development system 700 for developing a hardware system 702 in accordance with some embodiments. The system 700 includes a smart model 704 and a software system 703. The smart model 704 may be an example of the smart model 204 (FIG. 2), 304 (FIG. 3), and/or 404 (FIG. 4). The software system 703 may be an example of the software/API ecosystem 202 (FIG. 2) or 302 (FIG. 3). The smart model 704 is used to test software (e.g., an application) in the software system 703. The software (e.g., software 928, FIG. 9) may access and communicate with the smart model 704 through an API (e.g., API 930, FIG. 9). The hardware system 702 under test is an example of a DUT undergoing system-level test 110 (FIGS. 2 and/or 3).

The smart model 704 includes a model configurator and management module 706, data logger 708, parser 710, training- and test-set generator 712, model-training module 714, and model writer and deployment module 716. The model configurator and management module 706, which configures the smart model 704, is communicatively coupled with the data logger 708, parser 710, training- and test-set generator 712, model-training module 714, and model writer and deployment module 716. The data logger 708 logs raw input received from the software in the software system 703 and may log output of the smart model 704. The parser 710 generates embeddings and any metadata that are specific to the hardware system as modeled in the models 104, 106, and/or 108 and/or tested in system-level testing 110. The training- and test-set generator 712 transcodes test and training data (e.g., using a template) into a format that the model configurator and management module 706 can process. The model training module 714 controls performance of supervised learning, with the model configurator and management module 706 updating the smart model based on the supervised-learning results. The model training module 714 may specify hyperparameter values for the smart model. The model writer and deployment module 716 finalizes the smart model for deployment.

Each component of the smart model 704 may correspond to a set of instructions to be executed by one or more processors to perform the functions of the component.

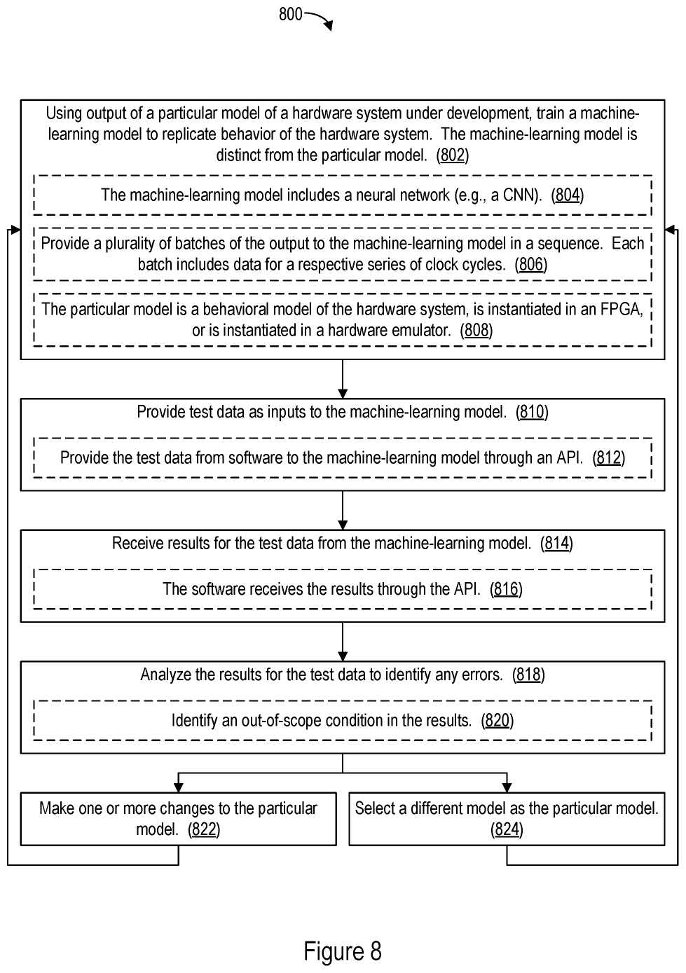

FIG. 8 is a flowchart illustrating a method 800 of developing a hardware system in accordance with some embodiments. The method 800 is performed, for example, in the development system 200 (FIG. 2), 300 (FIG. 3), and/or 700 (FIG. 7).

In the method 800, a machine-learning model (e.g., smart model 204, FIG. 2; 304, FIG. 3; 404, FIG. 4; and/or 704, FIG. 7) is trained (802) to replicate behavior of a hardware system that is under development. The training is performed using output of a particular model of the hardware system. The machine-learning model is distinct from the particular model. In some embodiments, the machine-learning model includes (804) a neural network (e.g., a convolutional neural network (CNN)).

To train the machine-learning model, output of the particular model (e.g., in the form of test data 600, FIG. 6) is provided as input to the machine-learning model. In some embodiments, a plurality of batches of the output is provided (806) as input to the machine-learning model in a sequence. Each batch includes test data for a respective series of clock cycles. The batches may be ordered in the sequence based on their respective series of clock cycles.

The clock cycles of respective batches of the plurality of batches, as provided to the machine-learning model, may overlap with the clock cycles of successive batches of the plurality of batches that are provided to the machine-learning model. For example, the plurality of batches may be provided to the machine-learning model in a sequence such that each batch (except the last batch in the sequence) has clock cycles that overlap the clock cycles of the next batch in the sequence.

Respective batches (e.g., each batch) of the plurality of batches may have a number of clock cycles equal to a multiple of a latency of the hardware system.

In some embodiments, the particular model is (808) a behavioral model of the hardware system (e.g., behavioral model 104, FIGS. 2 and/or 3), is a model of the hardware system that is instantiated in an FPGA (or other programmable logic) (e.g., FPGA prototype 106, FIGS. 2 and/or 3), or is a model of the hardware system that is instantiated in a hardware emulator (e.g., hardware emulator prototype 108, FIGS. 2 and/or 3).

In some embodiments, training the machine-learning model includes calculating a training loss. The training loss quantifies a difference (e.g., a percentage difference) between output of the machine-learning model and expected output of the machine-learning model during training. The training loss may be determined and tracked on a batch-by-batch basis, with a final training loss being determined for the machine-learning model once training is complete. For example, the final training loss may be the training loss achieved after a specified number of training cycles have been performed (e.g., in the training loop 504, FIG. 5) or may be a predetermined convergence criterion, such that training stops when the final training loss is achieved.

Test data is provided (810) as inputs to the machine-learning model. The test data may be provided to the machine-learning model from software that has been (or is being) developed for use with the hardware system (e.g., software in the software/API ecosystem 202, FIG. 2 or 302, FIG. 3; software in the software system 703, FIG. 7; software 928, FIG. 9). In some embodiments, the test data is provided (812) from the software to the machine-learning model through an API (e.g., an API in the software/API ecosystem 202, FIG. 2 or 302, FIG. 3; an API in the software system 703, FIG. 7; API 930, FIG. 9).

In some embodiments, after training (802) the machine-learning model but before providing (810) the test data to the machine-learning model, the machine-learning model is converted to (e.g., published as) run-time executable code. The test data is then provided (810) to the run-time executable code. Alternatively, the test data is provided to the machine-learning model with the machine-learning model in the same format in which it was trained.

Results for the test data are received (814) from the machine-learning model (e.g., from the run-time executable code). The results may be received by the software that provided that test data to the machine-learning model. In some embodiments, the software receives (816) the results through the API.

The results for the test data are analyzed (818) to identify any errors (e.g., using analysis module 932, FIG. 9). In some embodiments, this analysis includes identifying (820) an out-of-scope condition in the results and/or out-of-sequence results. The errors may include one or more errors in the particular model, one or more errors in the machine-learning model (e.g., due to training loss) and/or one or more errors in the software.

In some embodiments, analyzing the results includes calculating a test loss that quantifies a difference between the results for the test data and expected results for the test data. A determination is made as to whether the test loss matches the training loss. The test loss matches the training loss if the difference between the test loss and the training loss satisfies a matching criterion (e.g., the magnitude of the difference is less than, or less than or equal to, a threshold). The test loss does not match the training loss if the difference between the test loss and the training loss does not satisfy the matching criterion (e.g., the magnitude of the difference is greater than or equal to, or greater than, the threshold). Failure of the test loss to match the training loss may indicate that something is wrong with either the software or the machine-learning model (e.g., due to an underlying problem with the model used for training), such that the results are not legitimate. Accordingly, errors in the results may be ignored in response to determining that the test loss does not match the training loss, with focus put instead on fixing the software or the machine-learning model (e.g., on fixing the model used for training the machine-learning model). Errors may be accepted (i.e., treated as legitimate errors to be debugged) in response to determining that the test loss matches the training loss.

The method 800 may further include making (822) one or more changes to the particular model. These changes may be made in response to errors identified in step 818 and/or independently of the results in step 818, as part of an ongoing hardware-development process. In response to the one or more changes, another iteration of the method 800 is performed. The machine-learning model is retrained (802) using new output from the particular model (i.e., from the particular model as updated with the one or more changes). New output is thus obtained from the updated particular model in accordance with the one or more changes. After re-training the machine-learning model, test data is provided (810) as inputs to the machine-learning model. This test data may be referred to as second test data, while the test data used in the previous (e.g., initial) iteration of the method 800 may be referred to as first test data. The second test data may be identical to or different from the first test data. Results for the second test data are received (814) from the machine-learning model and are analyzed (818) to identify any errors.

Alternatively or in addition to making (822) one or more changes to the particular model and then performing another iteration of the method 800, the method 800 may further include selecting (824) a different model as the particular model and then performing another iteration of the method 800. For example, a first (e.g., initial) iteration of the method 800 may be performed in which a first model (e.g., a behavioral model of the hardware system (e.g., behavioral model 104, FIGS. 2 and/or 3)) is used to train (802) the machine-learning model and first test data is provided (810) as inputs to the machine-learning model. A second iteration of the method 800 may be performed (e.g., after the first iteration) in which a second model (e.g., a model instantiated in an FPGA or other programmable logic (e.g., FPGA prototype 106, FIGS. 2 and/or 3)) is used to train (802) (e.g., to re-train) the machine-learning model and second test data is provided (810) as inputs to the machine-learning model. The second test data may be identical to or different from the first test data. Results for the second test data are received (814) from the machine-learning model and are analyzed (818) to identify any errors. A third iteration of the method 800 may be performed (e.g., after the first and/or second iterations) in which a third model (e.g., a model instantiated in a hardware emulator (e.g., hardware-emulator prototype 108, FIGS. 2 and/or 3)) is used to train (802) (e.g., to re-train) the machine-learning model and third test data is provided (810) as inputs to the machine-learning model. The third test data may be identical to or different from the second and/or first test data. Results for the third test data are received (814) from the machine-learning model and are analyzed (818) to identify any errors.

Once the hardware system (e.g., a system on a semiconductor chip or multiple interconnected semiconductor chips) (e.g., an ASIC) (e.g., a semiconductor package with chiplets) has been fabricated, a modified iteration of the method 800 may be performed in which the particular model is replaced with an instance of the hardware system itself (e.g., with a DUT for system-level test 110, FIGS. 2 and/or 3). This modified iteration may be performed, for example, after the first, second and/or third iterations of the method 800. In the modified iteration of the method 800, output of the instance of the hardware system is used to re-train the machine-learning model to replicate the behavior of the hardware system. After the machine-learning model has been re-trained using the output of the instance of the hardware system, test data is provided (810) as inputs to the machine-learning model. This test data may be referred to as fourth test data and may be identical to or different from the third, second, and/or first test data. Results for the fourth test data are received (814) from the machine-learning model and are analyzed (818) to identify any errors.

The method 800 provides cross-platform validation and allows bugs to be identified and fixed early during development of the hardware system.

FIG. 9 is a block diagram of a computer system 900 used for hardware development, in accordance with some embodiments. The computer system 900 typically includes one or more processors 902 (e.g., CPUs and/or graphical processing units (GPUs)), one or more network interfaces 904 (wired and/or wireless), user interfaces 906, memory 910, and one or more communication buses 905 interconnecting these components.

The user interfaces 906 may include a display 907 and one or more input devices 908 (e.g., a keyboard, mouse, touch-sensitive surface of the display 907, etc.). The display 907 may display graphical user interfaces regarding use of a smart model (e.g., the machine-learning model of the method 800, FIG. 8) to test software and models. For example, the display 907 may display test data 600, results of training a smart model, and/or errors found by analyzing the results for test data from the smart model.

Memory 910 includes volatile and/or non-volatile memory. Memory 910 (e.g., the non-volatile memory within memory 910) includes a non-transitory computer-readable storage medium. Memory 910 optionally includes one or more storage devices remotely located from the processors 902 and/or a non-transitory computer-readable storage medium that is removably inserted into the computer system 900. In some embodiments, memory 910 (e.g., the non-transitory computer-readable storage medium of memory 910) stores the following modules and data: an operating system 912 that includes procedures for handling various basic system services and for performing hardware-dependent tasks, a smart model module 914 (e.g., for training, deploying, and/or using the smart model 204, FIG. 2; 304, FIG. 3; 404, FIG. 4; and/or 704, FIG. 7) (e.g., for training, deploying, and/or using the machine-learning model of the method 800, FIG. 8), one or more model modules 916 for developing and using models that are distinct from the smart model, a system-level testing module 924 (e.g., for performing system-leveling testing 110, FIGS. 2-3), a software/API ecosystem module 926 (e.g., for implementing the software/API ecosystem 202, FIG. 2 and/or 302, FIG. 3) (e.g., for implementing the software system 703, FIG. 7), and a test bench and monitor module 934 (e.g., for implementing the test bench and monitor 402, FIG. 4). In some embodiments, the model modules 916 include a behavioral model module 918 (e.g., corresponding to the behavioral model 104, FIGS. 2-3), an FPGA prototype module 920 (e.g., corresponding to the FPGA prototype 106, FIGS. 2-3), and/or a hardware-emulator prototype module 922 (e.g., corresponding to the hardware emulator prototype 108, FIGS. 2-3). In some embodiments, the software/API ecosystem module 926 includes software 928 (e.g., an application), an API 930, and an analysis module 932 for analyzing the results for test data from the smart model.

The memory 910 includes instructions for performing the method 800 (FIG. 8) or a portion thereof.

Each of the modules stored in memory 910 corresponds to a set of instructions for performing one or more functions described herein. Separate modules need not be implemented as separate software programs. The modules and various subsets of the modules may be combined or otherwise re-arranged. In some embodiments, memory 910 stores a subset or superset of the modules and/or data structures identified above.

FIG. 9 is intended more as a functional description of the various features that may be present in a computer system used for hardware development than as a structural schematic. In practice, items shown separately could be combined and some items could be separated. For example, some items shown separately in FIG. 9 could be implemented on a single computer and single items could be implemented by one or more computers. The actual number of computers used to implement the computer system 900, and how features are allocated among them, will vary from one implementation to another.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

1. A method of hardware development, comprising:
using input to and output from a first model of a hardware system under development, training a machine-learning model of the hardware system, wherein:
the machine-learning model is distinct from the first model, and
the input comprises instructions for the first model and data to be processed in accordance with the instructions for the first model;
providing first test data as inputs to the machine-learning model, the first test data comprising first test instructions and data to be processed in accordance with the first test instructions;
receiving results for the first test data from the machine-learning model, the results comprising first test output from the machine-learning model; and
analyzing the results for the first test data to identify any errors.

2. The method of claim 1, wherein the machine-learning model comprises a neural network.

3. The method of claim 1, wherein analyzing the results comprises identifying an out-of-scope condition in the first test output.

4. The method of claim 1, wherein:
training the machine-learning model comprises providing a plurality of batches of the input to and the output from the first model to the machine-learning model in a sequence; and
each batch of the plurality of batches is for a respective series of clock cycles.

5. The method of claim 4, wherein the clock cycles of respective batches of the plurality of batches overlap with the clock cycles of successive batches of the plurality of batches.

6. The method of claim 4, wherein respective batches of the plurality of batches have a number of clock cycles equal to a multiple of a latency of the hardware system.

7. The method of claim 1, wherein:
the first test data is provided to the machine-learning model from software, the software being for use with the hardware system;
the software receives the results; and
the errors comprise one or more errors in at least one of the first model or the software.

8. The method of claim 7, wherein:
the software provides the first test data to the machine-learning model through an application programming interface (API); and
the software receives the results through the API.

9. The method of claim 1, wherein:
training the machine-learning model comprises calculating a training loss; and
analyzing the results comprises:
calculating a test loss, and
determining whether the test loss matches the training loss, comprising determining whether a difference between the test loss and the training loss satisfies a matching criterion.

10. The method of claim 9, wherein:
determining whether the test loss matches the training loss comprises determining that the test loss matches the training loss; and
analyzing the results comprises accepting the errors in response to determining that the test loss matches the training loss.

11. The method of claim 9, wherein:
determining whether the test loss matches the training loss comprises determining that the test loss does not match the training loss; and
analyzing the results comprises ignoring the errors in response to determining that the test loss does not match the training loss.

12. The method of claim 1, further comprising:
in response to one or more changes made to the first model after training the machine-learning model, re-training the machine-learning model using new output of the first model;
after re-training the machine-learning model, providing second test data as inputs to the machine-learning model, the second test data comprising second test instructions and data to be processed in accordance with the second test instructions;
receiving results for the second test data from the machine-learning model, the results comprising second test output from the machine-learning model; and
analyzing the results for the second test data to identify any errors.

13. (canceled)

14. The method of claim 1, wherein the first model is a behavioral model of the hardware system.

15. The method of claim 14, further comprising, after training the machine-learning model, providing the first test data, receiving the results for the first test data, and analyzing the results for the first test data:
using input to and output from a second model of the hardware system, re-training the machine-learning model of the hardware system, wherein:
the second model is distinct from the first model and the machine-learning model, and
the input to the second model comprises instructions for the second model and data to be processed in accordance with the instructions for the second model;
after re-training the machine-learning model using the output of the second model, providing second test data as inputs to the machine-learning model, the second test data comprising second test instructions and data to be processed in accordance with the second test instructions;
receiving results for the second test data from the machine-learning model; and
analyzing the results for the second test data to identify any errors.

16. The method of claim 15, wherein the second model is instantiated in a field-programmable gate array (FPGA).

17. The method of claim 16, further comprising, after analyzing the results for the second test data:
using input to and output from a third model of the hardware system, re-training the machine-learning model of the hardware system, wherein:
the third model is distinct from the first model, the second model, and the machine-learning model, and
the input to the third model comprises instructions for the third model and data to be processed in accordance with the instructions for the third model;
after re-training the machine-learning model using the output of the third model, providing third test data as inputs to the machine-learning model, the third test data comprising third test instructions and data to be processed in accordance with the third test instructions;
receiving results for the third test data from the machine-learning model; and
analyzing the results for the third test data to identify any errors.

18. The method of claim 17, wherein the third model is instantiated in a hardware emulator.

19. The method of claim 18, further comprising, after analyzing the results for the second test data and analyzing the results for the third test data:
using input to and output from an instance of the hardware system, re-training the machine-learning model of the hardware system, wherein the input to the instance of the hardware system comprises instructions for the instance of the hardware system and data to be processed in accordance with the instructions for the instance of the hardware system;
after re-training the machine-learning model using the output of the instance of the hardware system, providing fourth test data as inputs to the machine-learning model, the fourth test data comprising fourth test instructions and data to be processed in accordance with the fourth test instructions;
receiving results for the fourth test data from the machine-learning model; and
analyzing the results for the fourth test data to identify potential bugs in the hardware system.

20. The method of claim 19, wherein the hardware system comprises a system on a semiconductor chip.

21. A computer system, comprising:
one or more processors; and
memory storing one or more programs for execution by the one or more processors, the one or more programs including instructions for:
using input to and output from a first model of a hardware system under development, training a machine-learning model of the hardware system, wherein:
the machine-learning model is distinct from the first model, and
the input comprises instructions for the first model and data to be processed in accordance with the instructions for the first model;
providing first test data as inputs to the machine-learning model, the first test data comprising first test instructions and data to be processed in accordance with the first test instructions;
receiving results for the first test data from the machine-learning model, the results comprising first test output from the machine-learning model; and
analyzing the results for the first test data to identify any errors.

22. A non-transitory computer-readable storage medium storing one or more programs for execution by a computer system, the one or more programs including instructions for:
using input to and output from a first model of a hardware system under development, training a machine-learning model of the hardware system, wherein:
the machine-learning model is distinct from the first model, and
the input comprises instructions for the first model and data to be processed in accordance with the instructions for the first model;
providing first test data as inputs to the machine-learning model, the first test data comprising first test instructions and data to be processed in accordance with the first test instructions;
receiving results for the first test data from the machine-learning model, the results comprising first test output from the machine-learning model; and
analyzing the results for the first test data to identify any errors.
